(19) United States
(12) Patent Application Publication
(10) Pub. No.: US 2026/0289315 A1
(43) Pub. Date: Sep. 24, 2026

(54) GENETIC ALGORITHM ACCELERATOR AND CONTROL METHOD THEREOF

(71) Applicant: RESEARCH & BUSINESS FOUNDATION SUNGKYUNKWAN UNIVERSITY, Suwon-si (KR)

(72) Inventors: Bai Sun KONG, Suwon-si (KR); Mohammadhadi Baghbanmanesh, Suwon-si (KR)

(21) Appl. No.: 19/572,021

(22) Filed: Mar. 19, 2026

(30) Foreign Application Priority Data
Mar. 24, 2025 (KR) 10-2025-0037520

(51) Int. Cl. G06N 3/086; G06N 3/065

(52) U.S. Cl. CPC G06N 3/086; G06N 3/065

(57) ABSTRACT

An example embodiment of the present invention may provide a genetic algorithm accelerator including a crossbar array block in which a plurality of memristor devices are connected in a crossbar array structure, wherein resistance states of the memristor devices are set based on a chromosome such that each row of the crossbar array structure simulates the chromosome.

### CROSS-REFERENCE TO RELATED APPLICATION

This application claims the priority benefit of Korean Patent Application No. 10-2025-0037520 filed on Mar. 24, 2025 in the Korean Intellectual Property Office, the disclosures of which are incorporated herein by reference.

### BACKGROUND

### 1. Field

An embodiment relates to a memristive crossbar array-based genetic algorithm accelerator capable of accelerating operations for performing a genetic algorithm, and a control method thereof.

### 2. Description of the Related Art

A genetic algorithm is a probabilistic optimization technique searching for an optimal solution based on biological evolutionary principles. The genetic algorithm may operate in a manner of generating a next-generation population through operations including selection, crossover, and mutation in an initial population, and evaluating a fitness of each individual. Due to these characteristics, the genetic algorithm may be effectively utilized for optimization of various problems.

During crossover and mutation processes being major operations of the genetic algorithm, many calculations are required, and in particular, as the size of a population increases, a computational burden increases. To solve this, various hardware-based acceleration techniques have been studied. For example, hardware implementation of a genetic algorithm using an FPGA (Field Programmable Gate Array) has been studied from an early stage, and dedicated processors based on an ASIC (Application Specific Integrated Circuit) have also been developed together.

However, existing FPGA and ASIC-based genetic algorithm accelerators may contribute to improving an operation speed, but there is still a limit in achieving high performance due to a bottleneck phenomenon between data movement and computation. Particularly, in the existing accelerator structure, due to the separation of a processor and a memory, since a process of reading, processing, and re-storing information of a population from the memory is repeated, there is a problem requiring many clock cycles.

In order to overcome such limitations, there is a need for a new approach minimizing movement between a memory and a processor by simultaneously performing data storage and computation, and solving problems of computation speed and energy efficiency of existing hardware-based accelerators.

### SUMMARY

This Summary is provided to introduce a selection of concepts in a simplified form that is further described below in the Detailed Description. This Summary is not intended to identify key features or essential features of the claimed subject matter, nor is it intended to be used as an aid in determining the scope of the claimed subject matter.

In order to solve the above-described problems, an embodiment provides a genetic algorithm accelerator and a control method thereof capable of accelerating an operation of a genetic algorithm by utilizing a memristor-based crossbar array structure.

An example embodiment of the present invention may provide a genetic algorithm accelerator including a crossbar array block in which a plurality of memristor devices are connected in a crossbar array structure, wherein resistance states of the memristor devices are set based on a chromosome such that each row of the crossbar array structure simulates the chromosome.

According to an embodiment, the crossbar array block may include a first row simulating a first parent chromosome, a second row simulating a second parent chromosome, and remaining rows simulating a child chromosome in which a part of the first parent chromosome and a part of the second parent chromosome are mixed.

According to an embodiment, the child chromosome is generated by crossing over the part of the first parent chromosome and the part of the second parent chromosome based on a plurality of preset crossover points.

According to an embodiment, the child chromosome is generated by mapping the part of the first parent chromosome to the remaining rows based on the plurality of preset crossover points, and mapping the part of the second parent chromosome to a region to which the part of the first parent chromosome is not mapped.

According to an embodiment, the resistance states of some memristor devices in the crossbar array block are changed according to a preset algorithm.

According to an embodiment, the resistance states of some memristor devices in the crossbar array block are set to a relatively high resistance state through a reset operation, and thereafter the resistance states of some other memristor devices are set to a relatively low resistance state through a set operation.

According to an embodiment, the genetic algorithm accelerator further includes an evaluation circuit calculating fitness of the chromosome by performing a weighted sum operation based on preset weights corresponding to the respective memristor devices for each row comprised in the crossbar array block.

According to an embodiment, the evaluation circuit is based on a winner-take-all circuit.

According to an embodiment, the genetic algorithm accelerator further includes a readout circuit externally reading out a chromosome evaluated to have the highest fitness by the evaluation circuit.

According to an embodiment, each of the plurality of memristor devices comprises a selector transistor to prevent a sneak path current by allowing a current to flow when the corresponding memristor device is activated.

An example embodiment of the present invention may provide method for controlling a genetic algorithm accelerator including a crossbar array block in which a plurality of memristor devices are connected in a crossbar array structure, wherein resistance states of the memristor devices are set based on a chromosome such that each row of the crossbar array structure simulates the chromosome.

According to an embodiment, the crossbar array block includes a first row simulating a first parent chromosome, a second row simulating a second parent chromosome, and remaining rows simulating a child chromosome in which a part of the first parent chromosome and a part of the second parent chromosome are mixed.

According to an embodiment, the child chromosome is generated by crossing over the part of the first parent chromosome and the part of the second parent chromosome based on a plurality of preset crossover points.

According to an embodiment, the child chromosome is generated by mapping the part of the first parent chromosome to the remaining rows based on the plurality of preset crossover points, and mapping the part of the second parent chromosome to a region to which the part of the first parent chromosome is not mapped.

According to an embodiment, the resistance states of some memristor devices in the crossbar array block are changed according to a preset algorithm.

According to an embodiment, the resistance states of some memristor devices in the crossbar array block are set to a relatively high resistance state through a reset operation, and thereafter the resistance states of some other memristor devices are set to a relatively low resistance state through a set operation.

According to an embodiment, the genetic algorithm accelerator further comprises an evaluation circuit calculating fitness of the chromosome by performing a weighted sum operation based on preset weights corresponding to the respective memristor devices for each row comprised in the crossbar array block.

According to an embodiment, the evaluation circuit is based on a winner-take-all circuit.

According to an embodiment, the genetic algorithm accelerator further comprises a readout circuit externally reading out a chromosome evaluated to have the highest fitness by the evaluation circuit.

According to an embodiment, each of the plurality of memristor devices comprises a selector transistor to prevent a sneak path current by allowing a current to flow when the corresponding memristor device is activated.

According to a genetic algorithm accelerator and a control method thereof according to an embodiment, accelerating an operation of a genetic algorithm utilizing a memristor-based crossbar array structure resolves a data movement and computation bottleneck phenomenon, and remarkably improves computation efficiency by maximizing parallel computation.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a flowchart of a genetic algorithm according to an embodiment.

FIG. 2 is a schematic diagram illustrating a memristor and an operating principle thereof according to an embodiment.

FIG. 3 is a schematic diagram illustrating a chromosome according to an embodiment.

FIG. 4 is a schematic diagram of the genetic algorithm accelerator 1 of an embodiment.

FIG. 5 is a block diagram of the genetic algorithm accelerator 1 of an embodiment.

FIGS. 6 and 7 are schematic diagrams of a chromosome simulation process of the crossbar array block 20 according to an embodiment.

FIGS. 8A and 8B are schematic diagrams of a mutation operation process according to an embodiment.

FIG. 9 is a schematic diagram illustrating the evaluation circuit 30 and a fitness evaluation process thereof according to an embodiment.

FIG. 10 is a schematic diagram illustrating a process reading out a chromosome from the readout circuit 40 according to an embodiment.

Throughout the drawings and the detailed description, the same reference numerals may refer to the same, or like, elements. The drawings may not be to scale, and the relative size, proportions, and depiction of elements in the drawings may be exaggerated for clarity, illustration, and convenience.

### DETAILED DESCRIPTION

The advantages and features of the present invention, and methods for achieving the same, will become apparent with reference to the embodiments described below in conjunction with the accompanying drawings. However, the present invention is not limited to the embodiments disclosed herein and may be implemented in various different forms. These embodiments are provided merely to make the disclosure of the present invention complete and to fully convey the scope of the invention to those skilled in the art to which the present invention pertains, and the present invention is defined only by the scope of the appended claims.

The terms used in the present specification will be briefly described, and the present invention will then be described in detail.

The terms used in the present invention have been selected from generally used terms that are widely employed at present while taking into consideration the functions in the present invention. However, these terms may vary depending on the intention of those skilled in the art, precedents, the emergence of new technologies, or the like. In certain cases, terms arbitrarily selected by the applicant may also be used, and in such cases, the meanings of the terms will be described in detail in the corresponding portions of the description of the invention. Accordingly, the terms used in the present invention should be construed based not merely on the names of the terms but on the meanings of the terms and the overall contents of the present invention.

Throughout the present specification, when a portion is described as including a certain component, this means that the portion may further include other components rather than excluding other components, unless otherwise specifically stated. In addition, the terms such as “part,” “module,” and “unit” used in the present specification may refer to a unit that processes at least one function or operation.

Hereinafter, embodiments of the present invention will be described in detail with reference to the accompanying drawings so that those skilled in the art to which the present invention pertains can readily practice the invention. In the drawings, portions not related to the description are omitted in order to clearly explain the present invention.

Terms including ordinal numbers such as “first” and “second” may be used to describe various components, but the components are not limited by these terms. These terms are used only for the purpose of distinguishing one component from another. For example, a first component may be referred to as a second component without departing from the scope of the present invention, and similarly, a second component may also be referred to as a first component. The term “and/or” includes any one of a plurality of associated items or a combination of a plurality of associated items.

Hereinafter, the genetic algorithm accelerator 1 and the control method thereof of an embodiment will be described.

The genetic algorithm accelerator 1 and the control method thereof of an embodiment are technologies for accelerating a genetic algorithm. The genetic algorithm is a probabilistic optimization technique searching for an optimal solution by imitating a natural evolutionary process, and may search for the optimal solution by repeating a process of generating a new population by performing operations including crossover and mutation in an initial population, and selecting superior chromosome by evaluating a fitness in each population.

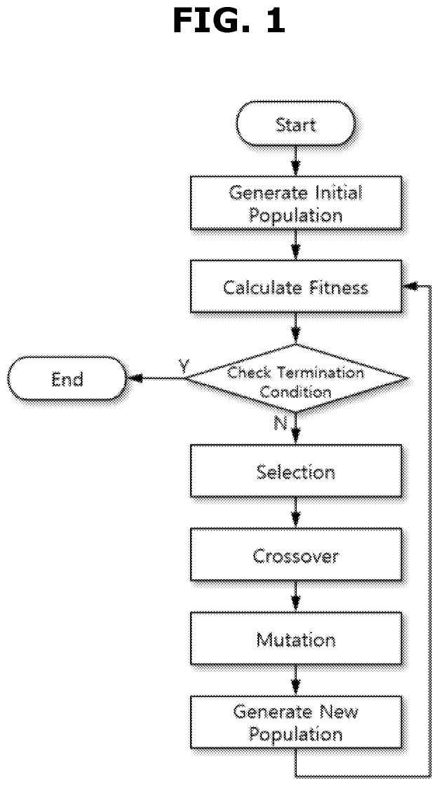

FIG. 1 is a flowchart of a genetic algorithm according to an embodiment.

Referring to FIG. 1, the genetic algorithm may include a process of calculating a fitness of each chromosome in an initial population, evaluating the fitness according to a criterion, and then selecting a most superior chromosome as a parent chromosome. Furthermore, the genetic algorithm may include a process of generating a child chromosome through crossover and mutation processes from the parent chromosome in order to generate a new population. Accordingly, the genetic algorithm may quickly converge to an optimal solution, and may exhibit high performance in various optimization problems.

The genetic algorithm accelerator 1 and the control method thereof of an embodiment are based on in-memory processing, thereby being capable of performing data storage and computation simultaneously.

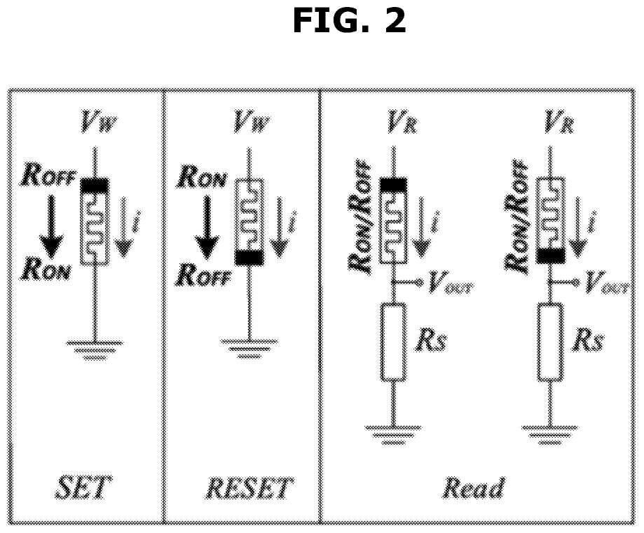

Specifically, the genetic algorithm accelerator 1 and the control method thereof of an embodiment may perform data storage and computation simultaneously utilizing a memristor. FIG. 2 is a schematic diagram illustrating a memristor and an operating principle thereof according to an embodiment. The memristor has a characteristic of changing a resistance value according to a previous voltage or current state by remembering a current flow path. If a voltage is applied in a specific direction, then the memristor may change to a low resistance state (ON) decreasing resistance, and if a voltage in an opposite direction is applied, then the memristor may transition to a high resistance state (OFF) increasing resistance. Since this resistance value is maintained even if power is turned off, the memristor may be used as a non-volatile memory.

The memristor-based crossbar array structure means that memristors having resistance values varying according to a history of a flowed current are arranged in an array structure having rows and columns. Accordingly, the memristor-based crossbar array structure may combine a memory function of the memristor and a parallel processing function of the array.

The genetic algorithm accelerator 1 and the control method thereof of an embodiment may accelerate a genetic algorithm utilizing the memristor-based crossbar array structure. Accordingly, an embodiment may remarkably improve the operation speed of the genetic algorithm, minimize a bottleneck phenomenon according to data movement, and maximize energy efficiency. Furthermore, an embodiment may overcome limitations of an existing hardware-based genetic algorithm accelerator, and effectively perform a large-scale parallel operation, improving optimal solution search performance.

Hereinafter, the genetic algorithm accelerator 1 of an embodiment will be described.

The genetic algorithm accelerator 1 of an embodiment may simulate a plurality of chromosomes utilizing memristor devices 210 arranged in a crossbar array structure, and may perform a genetic algorithm operation through a process of evaluating a fitness of each chromosome and selecting and reading out a chromosome having the highest fitness.

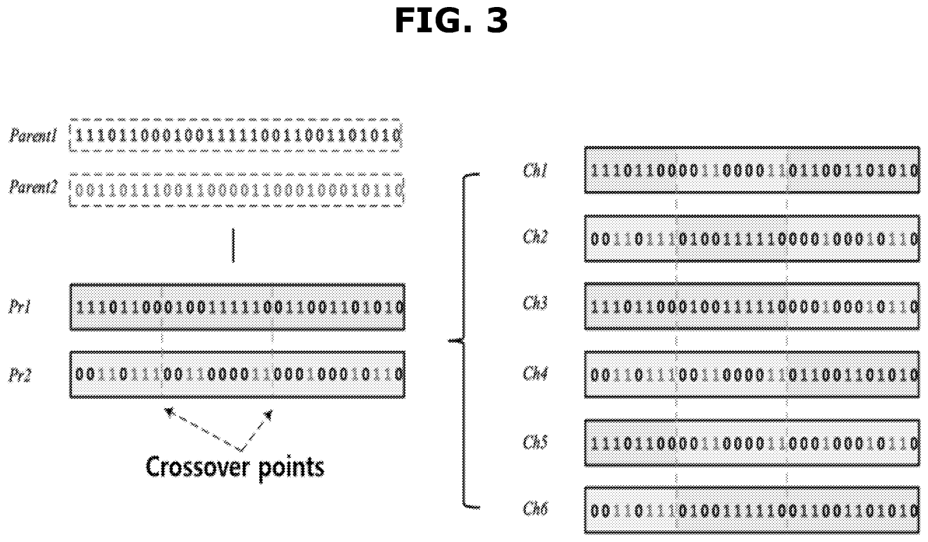

Here, a chromosome may mean a data structure expressing an individual solution in the genetic algorithm. FIG. 3 is a schematic diagram illustrating a chromosome according to an embodiment. In general, the chromosome includes genetic information, and may include a bit string of a specific length to express the genetic information digitally.

The chromosome may include a parent chromosome and a child chromosome. Referring to FIG. 3, parent chromosomes Pr1 and Pr2 may mean original chromosomes serving as a reference for performing a crossover operation, and child chromosomes Ch1 to Ch6 may mean new chromosomes generated by combining some gene data of the parent chromosomes. A specific portion of the child chromosome is selected from a first parent chromosome, and a remaining portion is selected from a second parent chromosome, being generated by performing a crossover operation.

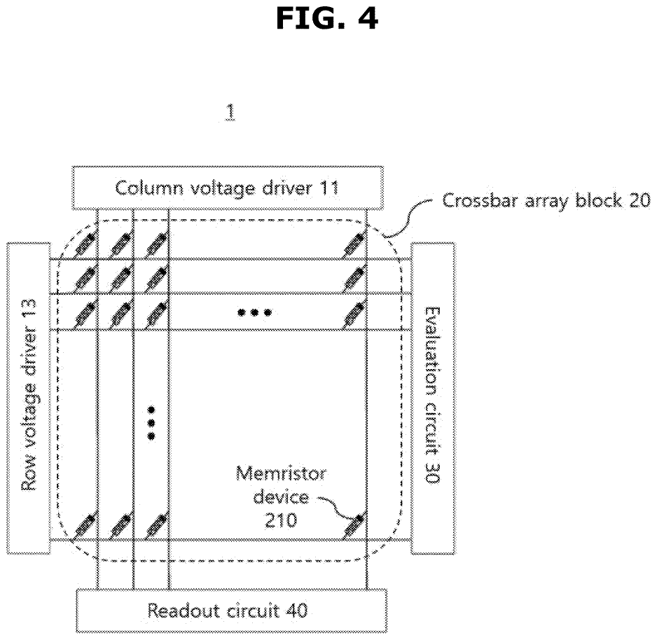

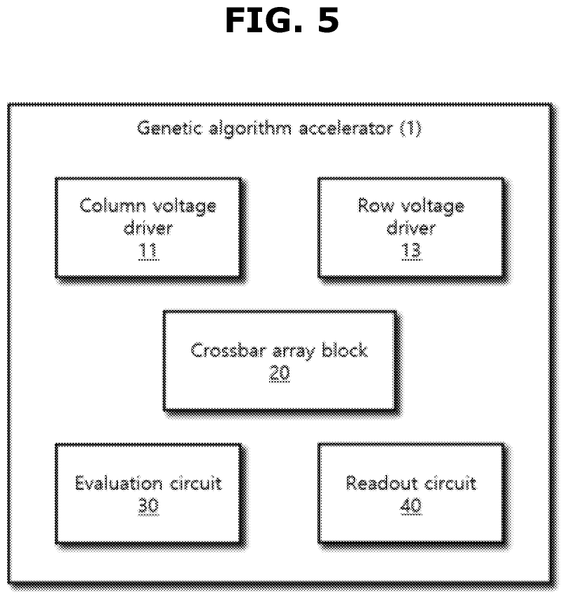

FIG. 4 is a schematic diagram of the genetic algorithm accelerator 1 of an embodiment, and FIG. 5 is a block diagram of the genetic algorithm accelerator 1 of an embodiment.

Referring to FIGS. 4 and 5, the genetic algorithm accelerator 1 of an embodiment may include a crossbar array block 20, a row voltage driver 13, a column voltage driver 11, an evaluation circuit 30, and a readout circuit 40. The genetic algorithm accelerator 1 of an embodiment may further include a processor providing signals, a memory storing data, a DFF (D Flip-Flop), and the like, in addition to the configuration described above.

The row voltage driver 13 and the column voltage driver 11 are driving circuits applying a voltage required to perform a genetic algorithm operation in the crossbar array block 20. The row voltage driver 13 and the column voltage driver 11 may individually select each row and column of the crossbar array block 20 to supply a specific voltage, allowing a selected row to simulate a chromosome.

The row voltage driver 13 and the column voltage driver 11 may allow other components including the crossbar array block 20 and the evaluation circuit 30 to store and update respective chromosome data during a genetic algorithm operation process including crossover, mutation, and fitness evaluation to be described later. In one embodiment, during a crossover operation, the row voltage driver 13 may select a row storing a parent chromosome, and the column voltage driver 11 may determine a column generating a child chromosome, applying a voltage based thereon. Furthermore, during a mutation operation, in order to change resistance states of some memristor devices 210 in a row simulating a specific chromosome, the row voltage driver 13 may select a row of a corresponding chromosome, and the column voltage driver 11 may supply a voltage to change the resistance state of a selected memristor device 210. In addition, during a fitness evaluation process, the column voltage driver 11 may apply a voltage reflecting a preset weight value to each column, and the row voltage driver 13 may transfer data to the evaluation circuit 30 based on this, allowing an operation of all chromosomes to be performed.

That is, it may be understood that the following genetic algorithm operation process is achieved by the row voltage driver 13 and the column voltage driver 11 operating by a user manipulation or a preset algorithm to provide a voltage to respective components.

The crossbar array block 20 may include a plurality of memristor devices 210 connected in a crossbar array structure. The crossbar array structure is formed in a form where a plurality of rows and columns cross, and each of the plurality of memristor devices 210 may be disposed at an intersection where a row and a column cross. The memristor devices 210 have a characteristic changing their resistance states if a specific voltage is applied, utilizing this to store data or perform calculations. That is, each memristor device 210 may have a specific resistance state, utilizing this to represent information. For example, the memristor devices 210 may store information on digital data by setting bit 1 to a low resistance state (ON) and 0 to a high resistance state (OFF).

According to an embodiment, the memristor devices 210 may further include a selector transistor. During a genetic algorithm operation process, a sneak path current may flow to an unintended memristor device 210 in addition to a memristor device 210 intended for a resistance change. Due to this, a sneak path current problem may occur during crossover and mutation operation processes described later, but if the memristor devices 210 further include a selector transistor, then a current may be allowed to flow when the memristor devices 210 are activated, preventing such a sneak path current from occurring, preventing power overhead.

Each row and column of the crossbar array block 20 may be connected to the row voltage driver 13 and the column voltage driver 11, applying a voltage to a specific row or column thereby to set or read a state of the memristor devices 210. The resistance states of the memristor devices 210 may be adjusted according to whether a voltage is applied and a magnitude thereof, performing an operation within the crossbar array thereby. Due to the crossbar array structure of the crossbar array block 20, the resistance states of the memristor devices 210 may be individually changed, and resistance states of a plurality of memristor devices 210 may be simultaneously changed.

The crossbar array block 20 may have the resistance states of the memristor devices 210 set based on a chromosome, allowing each row included therein to simulate the chromosome. In the crossbar array, each row may be allocated as a data region storing one chromosome, and each column may correspond to an individual gene bit constituting the chromosome. Data constituting the chromosome may be written to the memristor devices 210 through the row voltage driver 13 and the column voltage driver 11, and a resistance state of a specific memristor device 210 may be changed according to a given voltage condition.

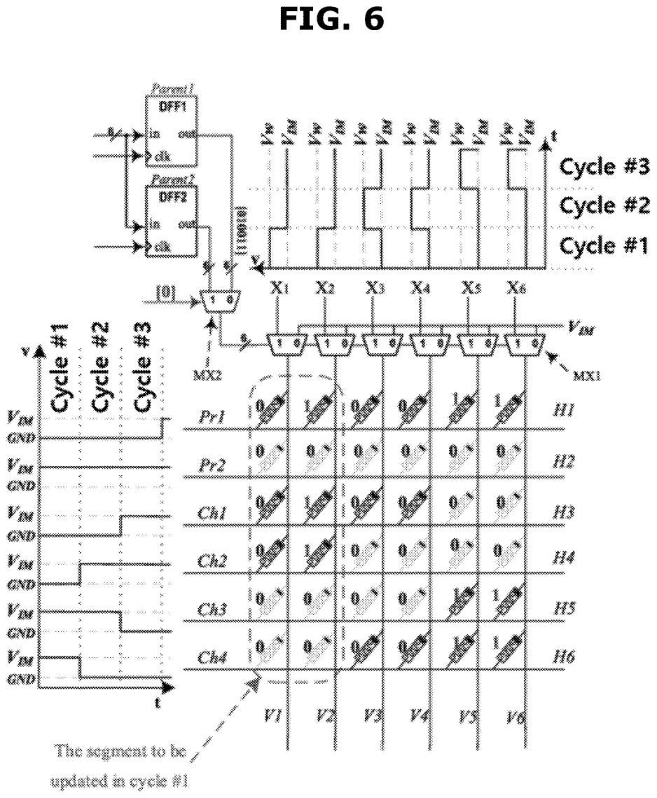

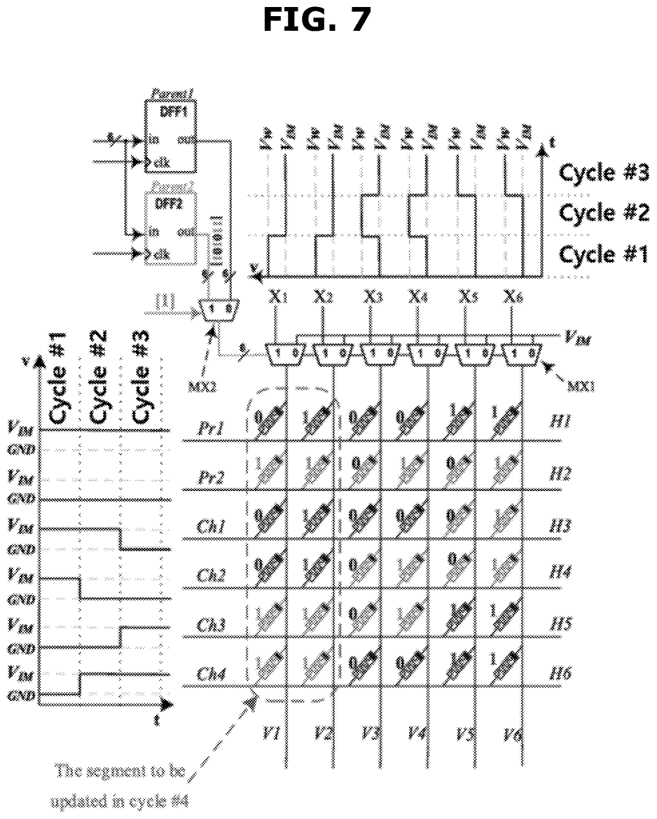

FIGS. 6 and 7 are schematic diagrams of a chromosome simulation process of the crossbar array block 20 according to an embodiment.

Referring to FIGS. 6 and 7, the memristor devices 210 of the crossbar array block 20 may have resistance states changed to simulate a specific chromosome according to voltages provided from the column voltage driver 11 and the row voltage driver 13. According to the embodiment of FIG. 6, if the parent chromosome is 010011, then the memristor devices 210 in a row simulating this may be sequentially set to a high resistance state, a low resistance state, a high resistance state, a high resistance state, a low resistance state, and a low resistance state.

The memristor devices 210 of the crossbar array block 20 may simulate a chromosome by voltages according to a plurality of clock cycles. A clock cycle may mean a time unit required for one operation to be completed within a circuit. In one clock cycle, a change in resistance may be induced by providing a voltage to the memristor devices 210 of the crossbar array block 20 through a control circuit including a DFF and a multiplexer according to a clock signal, allowing data to be inputted or read out thereby. Referring to the embodiments of FIGS. 6 and 7, the memristor devices 210 may change or maintain resistance depending on whether a row voltage is V_{IM} or GND and whether a column voltage is V_{W} or V_{IM}, simulating a chromosome according to this.

In the genetic algorithm accelerator 1 of an embodiment, the clock cycle may determine a timing performing crossover and mutation operations. In one embodiment, a part of a parent chromosome is selected in a specific clock cycle, changing data for a specific column based on this, generating a child chromosome thereby. A process of simulating a chromosome according to a clock cycle and generating a child chromosome will be described later.

The crossbar array block 20 may include a first row simulating a first parent chromosome, a second row simulating a second parent chromosome, and remaining rows simulating a child chromosome mixing a part of the first parent chromosome and a part of the second parent chromosome. In the crossbar array of the crossbar array block 20, the first row and the second row may be allocated to store the first parent chromosome and the second parent chromosome respectively, and the memristor devices 210 of each row may be set to resistance states reflecting genetic data of the corresponding parent chromosome.

Remaining rows excluding the first row and the second row in the crossbar array of the crossbar array block 20 may store the child chromosome. The crossbar array block 20 may store the child chromosome generated from the parent chromosome through a crossover operation. Referring to FIG. 7, in one row of the crossbar array block 20, the memristor devices 210 in a specific region or column are set to data of the first parent chromosome, and the memristor devices 210 in another region or column are set to data of the second parent chromosome, being stored. In the process of performing such a crossover operation, a gene value of a selected parent chromosome may be copied to a resistance state of a corresponding memristor device 210, and such data transmission may be controlled through the row voltage driver 13 and the column voltage driver 11.

The child chromosome may be generated by crossing over parts of the first parent chromosome and the second parent chromosome based on a plurality of preset crossover points. As described above, the child chromosome may be generated by crossing over parts of the first parent chromosome and the second parent chromosome. In the crossbar array, each row is allocated to store one chromosome, and rows storing the child chromosome may be configured by selectively combining some data of the parent chromosome through a crossover operation. A crossover point may be set to a predefined specific column position, and a crossover operation may be performed by copying genes of different parent chromosomes based on the corresponding crossover point. Furthermore, if a plurality of crossover points exist, then a child chromosome may be generated in a manner combining data of different parent chromosomes respectively in multiple divided regions, allowing the child chromosome to form a new combination while maintaining some characteristics of the parent chromosome thereby.

According to an embodiment, the number of crossover points may be set to a number satisfying Equation 1 below.

$${N}_{CP} \geq {log}_{2} ( P ) - 1 \qquad [ Equation l ]$$

$${N}_{CK} = ( {N}_{CP} + 1 ) \times 2$$

Here, N_{CP} may mean the number of crossover points, P may mean the number of chromosomes in a population, and N_{CK} may mean the number of clock cycles required to complete all crossover operations during one generation.

The child chromosome may be generated by mapping a part of the first parent chromosome to rows of the crossbar array block 20 based on the plurality of crossover points, and mapping a part of the second parent chromosome to an unassigned region. Rows storing the child chromosome within the crossbar array may be allocated as a data region performing a crossover operation, and a part of the parent chromosome may be mapped to a specific column position of each row according to a preset crossover point. The crossover point becomes a reference for exchanging data between parent chromosomes within the child chromosome, and genetic data before the corresponding crossover point is copied from the first parent chromosome, and an unspecified region thereafter may be set to reflect data of the second parent chromosome. Such a mapping process may be performed in a manner applying a voltage utilizing the row voltage driver 13 and the column voltage driver 11, determining a gene value of the child chromosome by adjusting a resistance state of a selected memristor device 210. Furthermore, if a plurality of crossover points exist, then data of the parent chromosome may be mapped by being divided into a plurality of sections according to positions of the crossover points, being arranged to generate child chromosomes of various combinations thereby.

Referring to FIGS. 6 and 7, FIG. 6 illustrates a process performing an initial crossover. DFF1 and DFF2 store data of a first parent chromosome and a second parent chromosome respectively, having a structure selectively applying this data to specific rows and columns of a crossbar array through multiplexers MX1 and MX2. In the initial crossover process, as shown in FIG. 6, some regions may be updated based on the first parent chromosome data based on a preset crossover point. FIG. 7 illustrates a process performing a subsequent crossover. In the subsequent crossover process, by updating a remaining region not updated with the first parent chromosome in a previous operation utilizing second parent chromosome data, a child chromosome subjected to a crossover operation based on a crossover point is generated, being stored in each row.

Referring to the embodiments of FIGS. 6 and 7, the memristor devices 210 of the crossbar array block 20 may simulate a chromosome as a total of six clock cycles Cycle #1 to #6 proceed from a first clock cycle to a sixth clock cycle.

Referring to the embodiment of FIG. 6, the crossbar array block 20 may simulate a first parent chromosome and a part thereof during an initial crossover operation process.

In a first clock cycle Cycle #1, a part of the first parent chromosome may be copied to the left region of a first row H1, a third row H3, and a fourth row H4 of the crossbar array block 20. To this end, in the first clock cycle Cycle #1, voltages of a first left line V1 and a second line V2 are set to V_{W} in a vertical line, and voltages of a first row H1, a third row H3, and a fourth row H4 may be set to GND in a horizontal line.

Next, in a second clock cycle Cycle #2, a part of the first parent chromosome may be copied to a middle region of the first row H1, the third row H3, and a sixth row H6 of the crossbar array block 20. To this end, in the second clock cycle Cycle #2, voltages of a third line V3 and a fourth line V4 are set to V_{W} in the vertical line, and voltages of the first row H1, the third row H3, and the sixth row H6 may be set to GND in the horizontal line.

Next, in a third clock cycle Cycle #3, a part of the first parent chromosome may be copied to a right region of the first row H1, a fifth row H5, and the sixth row H6 of the crossbar array block 20. To this end, in the third clock cycle Cycle #3, voltages of a fifth line V5 and a sixth line V6 are set to V_{W} in the vertical line, and voltages of the first row H1, the fifth row H5, and the sixth row H6 may be set to GND in the horizontal line.

Referring to the embodiment of FIG. 7, the crossbar array block 20 may simulate a second parent chromosome and a part thereof in a region not simulated during the initial crossover operation process during a subsequent crossover operation process.

In a fourth clock cycle Cycle #4, a part of the second parent chromosome may be copied to a left region of the second row H2, the fifth row H5, and the sixth row H6 of the crossbar array block 20. To this end, in the fourth clock cycle Cycle #4, voltages of the first left line V1 and the second line V2 are set to V_{W} in the vertical line, and voltages of the second row H2, the fifth row H5, and the sixth row H6 may be set to GND in the horizontal line.

Next, in a fifth clock cycle Cycle #5, a part of the second parent chromosome may be copied to a middle region of the second row H2, the fourth row H4, and the fifth row H5 of the crossbar array block 20. To this end, in the fifth clock cycle Cycle #5, voltages of the third line V3 and the fourth line V4 are set to V_{W} in the vertical line, and voltages of the second row H2, the fourth row H4, and the fifth row H5 may be set to GND in the horizontal line.

Next, in a sixth clock cycle Cycle #6, a part of the second parent chromosome may be copied to the right region of the second row H2, the third row H3, and the fourth row H4 of the crossbar array block 20. To this end, in the sixth clock cycle Cycle #6, voltages of the fifth line V5 and the sixth line V6 are set to V_{W} in the vertical line, and voltages of the second row H2, the third row H3, and the fourth row H4 may be set to GND in the horizontal line.

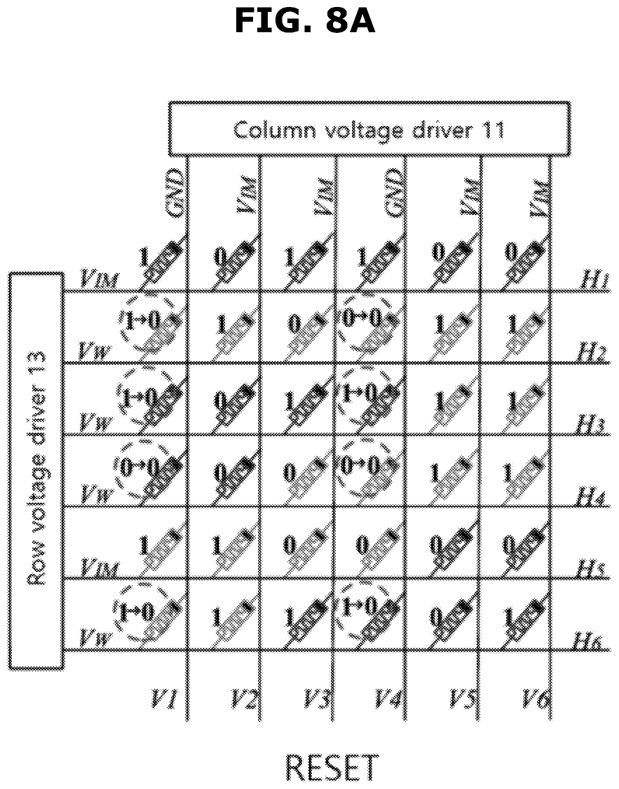

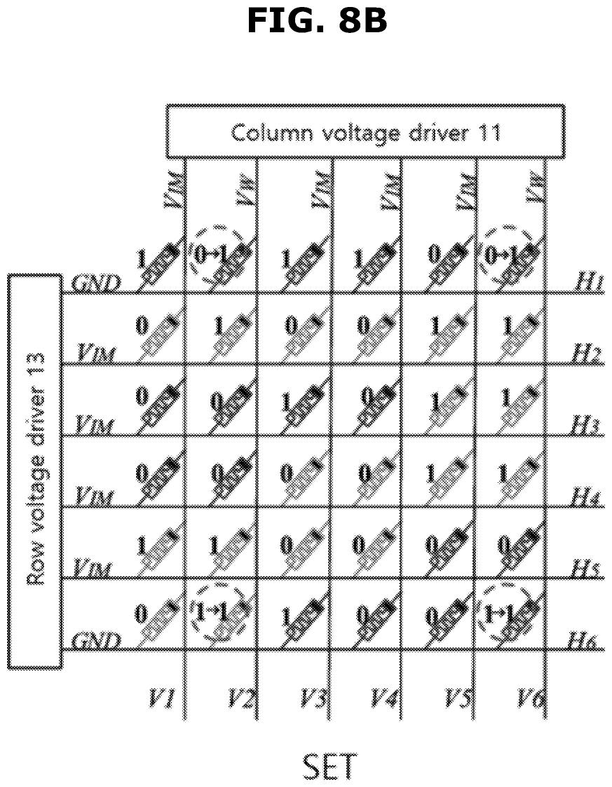

The crossbar array block 20 may simulate a mutation by changing resistance states of some memristor devices 210. FIGS. 8A and 8B are schematic diagrams of a mutation operation process according to an embodiment. A mutation operation may be performed by changing a resistance state of a memristor device 210 selected within the crossbar array, and for this purpose, a voltage may be applied to a memristor device 210 at a specific position utilizing the row voltage driver 13 and the column voltage driver 11. The memristor device 210 being a mutation target may be selected according to a preset probability or rule, and the selected memristor device 210 may be transitioned from an existing resistance state to an opposite state. For example, a memristor device 210 originally in a low resistance state (ON) may transition to a high resistance state (OFF), and conversely, a memristor device 210 in a high resistance state (OFF) may be changed to a low resistance state (ON). Such a mutation operation may be performed within a specific clock cycle, and after the mutation is applied, voltage application may be adjusted to maintain the changed state of the memristor device 210. Furthermore, the mutation operation may be performed in parallel within the crossbar array to simultaneously mutate selected memristor devices 210 thereby.

The crossbar array block 20 may have resistance states of some memristor devices 210 set to a relatively high resistance state through a reset operation, and thereafter resistance states of some other memristor devices 210 may be set to a relatively low resistance state through a set operation. The reset operation may be performed in a manner applying a specific voltage to a selected memristor device 210 to increase resistance state, setting the corresponding memristor device 210 to a high resistance state (OFF) thereby. The set operation is performed in an opposite manner to the reset operation, and applies a different voltage condition to a selected memristor device 210 to decrease resistance state, being set to a low resistance state (ON) thereby. Such reset and set operations may be sequentially performed by selecting a specific row and column within the crossbar array block 20, being performed by controlling an applied voltage utilizing the row voltage driver 13 and the column voltage driver 11.

The evaluation circuit 30 may evaluate the fitness of a chromosome simulated by each row of the crossbar array block 20. The evaluation circuit 30 may be arranged in a structure receiving chromosome data stored in each row of the crossbar array as an input, calculating fitness according to predefined criteria.

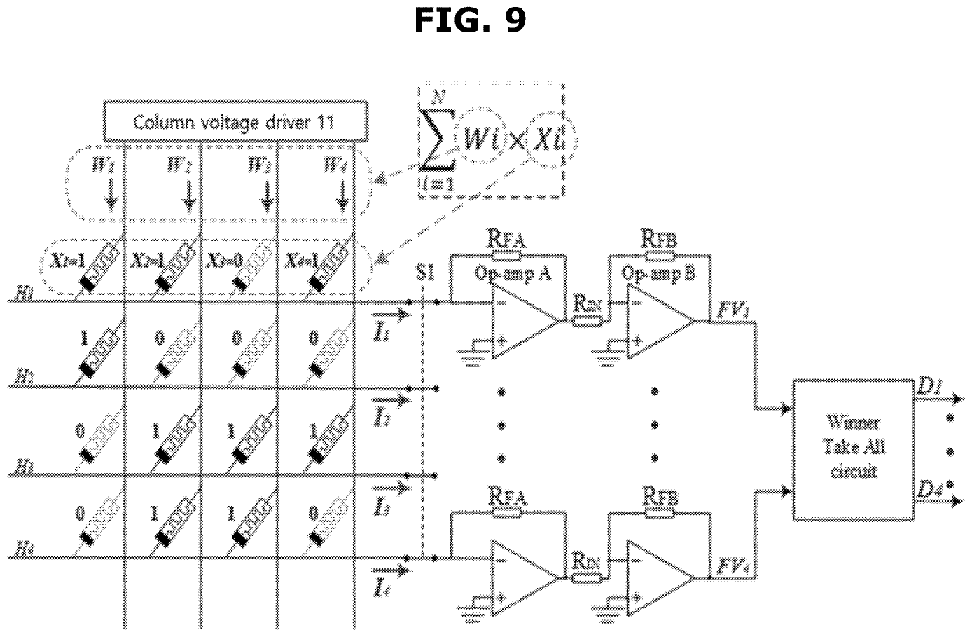

FIG. 9 is a schematic diagram illustrating the evaluation circuit 30 and a fitness evaluation process thereof according to an embodiment.

The memristor devices 210 of each row indicate a gene value of a corresponding chromosome, and the evaluation circuit 30 may calculate fitness based on the state of each memristor device 210. To this end, the evaluation circuit 30 may be arranged to apply an input voltage in units of columns of the crossbar array, and allow a corresponding voltage to be converted into a current according to resistance states of the memristor devices 210. A converted current value is summed through an operation circuit, and the fitness of a chromosome simulated by a corresponding row may be determined utilizing this value. A fitness operation method may be performed by a weighted sum operation or a method calculating the number satisfying a specific condition, and to this end, the evaluation circuit 30 may include a function outputting an operation result. Furthermore, the evaluated fitness value may be compared with other chromosomes through a comparison circuit operable to select a chromosome having a high fitness or perform an additional genetic operation thereby.

The evaluation circuit 30 may calculate the fitness of a chromosome by performing a weighted sum operation based on preset weights corresponding to respective memristor devices 210 for each row included in the crossbar array block 20. In the crossbar array block 20, each row stores one chromosome, and each memristor device 210 may represent an individual gene value of a corresponding chromosome. The evaluation circuit 30 may apply a voltage to which a weight is applied based on a state of a memristor device 210 corresponding to each column in order to calculate a fitness of a chromosome, and a corresponding voltage may be converted into a current according to resistance states of the memristor devices 210. A converted current is summed through an operation circuit, being output as a final fitness value. A weight may be set according to predefined criteria, performing a role adjusting a contribution of each gene value according to characteristics of an optimization problem a chromosome intends to solve. Furthermore, a weighted sum operation result may be transferred to a fitness comparison circuit operable to perform a comparison with other chromosomes or an additional genetic operation thereby.

The evaluation circuit 30 may be based on a winner-take-all circuit. The winner-take-all circuit is a circuit selecting and outputting an input having the highest value among a plurality of input values, identifying a chromosome having the highest fitness by comparing fitness of a chromosome stored by each row within the crossbar array. The evaluation circuit 30 calculates fitness of each chromosome, and then performs a comparison operation through the winner-take-all circuit, selecting a chromosome having the highest fitness according to a comparison result. To this end, the winner-take-all circuit may operate in a manner receiving each fitness value as an input, and activating an input having a maximum value satisfying a specific criterion. A selected chromosome may be transmitted to a separate circuit to be utilized as a parent chromosome for a subsequent genetic operation, and an additional comparison operation may be performed as needed. According to an embodiment, the winner-take-all circuit may be implemented as a multi-stage comparison structure, being operable to select a plurality of chromosomes having high fitness thereby.

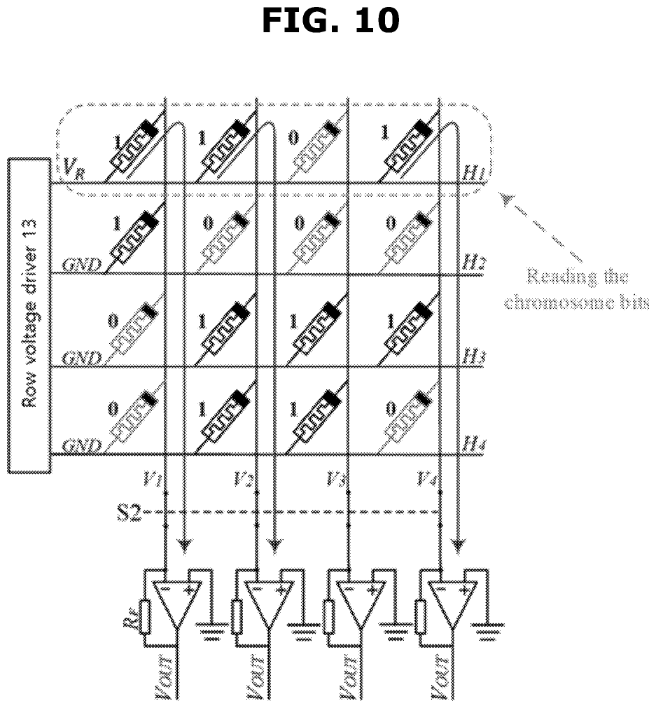

The readout circuit 40 may read out a chromosome evaluated to have the highest fitness by the evaluation circuit 30 to the outside. FIG. 10 is a schematic diagram illustrating a process reading out a chromosome from the readout circuit 40 according to an embodiment. The readout circuit 40 may operate in a manner activating a row storing a selected chromosome within the crossbar array, and outputting data by sensing a resistance state of a memristor device 210 of a corresponding row. To this end, the readout circuit 40 receives a row selection signal, applying a read voltage to a memristor device 210 corresponding to a specific row, obtaining chromosome data by sensing a generated current according to this. A sensed current may be converted into a digital signal through an operation circuit, and a converted signal may be transmitted to an external storage device or a subsequent operation circuit. Furthermore, the readout circuit 40 may include a differential amplifier or a sense amplifier to minimize signal interference and guarantee accurate data output, being operable to perform a function sequentially reading out multiple chromosomes as needed.

Hereinafter, a method for controlling the genetic algorithm accelerator (1) according to the present invention will be described.

An example embodiment of the present invention may provide method for controlling a genetic algorithm accelerator including a crossbar array block in which a plurality of memristor devices are connected in a crossbar array structure, wherein resistance states of the memristor devices are set based on a chromosome such that each row of the crossbar array structure simulates the chromosome.

According to an embodiment, the crossbar array block includes a first row simulating a first parent chromosome, a second row simulating a second parent chromosome, and remaining rows simulating a child chromosome in which a part of the first parent chromosome and a part of the second parent chromosome are mixed.

According to an embodiment, the child chromosome is generated by crossing over the part of the first parent chromosome and the part of the second parent chromosome based on a plurality of preset crossover points.

According to an embodiment, the child chromosome is generated by mapping the part of the first parent chromosome to the remaining rows based on the plurality of preset crossover points, and mapping the part of the second parent chromosome to a region to which the part of the first parent chromosome is not mapped.

According to an embodiment, the resistance states of some memristor devices in the crossbar array block are changed according to a preset algorithm.

According to an embodiment, the resistance states of some memristor devices in the crossbar array block are set to a relatively high resistance state through a reset operation, and thereafter the resistance states of some other memristor devices are set to a relatively low resistance state through a set operation.

According to an embodiment, the genetic algorithm accelerator further comprises an evaluation circuit calculating fitness of the chromosome by performing a weighted sum operation based on preset weights corresponding to the respective memristor devices for each row comprised in the crossbar array block.

According to an embodiment, the evaluation circuit is based on a winner-take-all circuit.

According to an embodiment, the genetic algorithm accelerator further comprises a readout circuit externally reading out a chromosome evaluated to have the highest fitness by the evaluation circuit.

According to an embodiment, each of the plurality of memristor devices comprises a selector transistor to prevent a sneak path current by allowing a current to flow when the corresponding memristor device is activated.

Those skilled in the art related to the embodiments of the present invention will understand that the invention may be implemented in modified forms without departing from the essential characteristics described above. Accordingly, the disclosed embodiments should be considered in an illustrative rather than a limiting sense. The scope of the present invention is defined by the appended claims rather than by the detailed description, and all differences within the equivalent scope thereof should be construed as being included in the scope of the present invention.

What is claimed is:

1. A genetic algorithm accelerator comprising:
a crossbar array block in which a plurality of memristor devices are connected in a crossbar array structure, wherein resistance states of the memristor devices are set based on a chromosome such that each row of the crossbar array structure simulates the chromosome.

2. The genetic algorithm accelerator of claim 1,
wherein the crossbar array block comprises:
a first row simulating a first parent chromosome,
a second row simulating a second parent chromosome, and
remaining rows simulating a child chromosome in which a part of the first parent chromosome and a part of the second parent chromosome are mixed.

3. The genetic algorithm accelerator of claim 2,
wherein the child chromosome is generated by crossing over the part of the first parent chromosome and the part of the second parent chromosome based on a plurality of preset crossover points.

4. The genetic algorithm accelerator of claim 3,
wherein the child chromosome is generated by mapping the part of the first parent chromosome to the remaining rows based on the plurality of preset crossover points, and mapping the part of the second parent chromosome to a region to which the part of the first parent chromosome is not mapped.

5. The genetic algorithm accelerator of claim 1,
wherein the resistance states of some memristor devices in the crossbar array block are changed according to a preset algorithm.

6. The genetic algorithm accelerator of claim 5,
wherein the resistance states of some memristor devices in the crossbar array block are set to a relatively high resistance state through a reset operation, and thereafter the resistance states of some other memristor devices are set to a relatively low resistance state through a set operation.

7. The genetic algorithm accelerator of claim 1, further comprising:
an evaluation circuit calculating fitness of the chromosome by performing a weighted sum operation based on preset weights corresponding to the respective memristor devices for each row comprised in the crossbar array block.

8. The genetic algorithm accelerator of claim 7,
wherein the evaluation circuit is based on a winner-take-all circuit.

9. The genetic algorithm accelerator of claim 7, further comprising:
a readout circuit externally reading out a chromosome evaluated to have the highest fitness by the evaluation circuit.

10. The genetic algorithm accelerator of claim 1,
wherein each of the plurality of memristor devices comprises a selector transistor to prevent a sneak path current by allowing a current to flow when the corresponding memristor device is activated.

11. A method for controlling a genetic algorithm accelerator comprising a crossbar array block in which a plurality of memristor devices are connected in a crossbar array structure, wherein resistance states of the memristor devices are set based on a chromosome such that each row of the crossbar array structure simulates the chromosome.

12. The method for controlling a genetic algorithm accelerator of claim 11,
wherein the crossbar array block comprises:
a first row simulating a first parent chromosome,
a second row simulating a second parent chromosome, and
remaining rows simulating a child chromosome in which a part of the first parent chromosome and a part of the second parent chromosome are mixed.

13. The method for controlling a genetic algorithm accelerator of claim 12,
wherein the child chromosome is generated by crossing over the part of the first parent chromosome and the part of the second parent chromosome based on a plurality of preset crossover points.

14. The method for controlling a genetic algorithm accelerator of claim 13,
wherein the child chromosome is generated by mapping the part of the first parent chromosome to the remaining rows based on the plurality of preset crossover points, and mapping the part of the second parent chromosome to a region to which the part of the first parent chromosome is not mapped.

15. The method for controlling a genetic algorithm accelerator of claim 11,
wherein the resistance states of some memristor devices in the crossbar array block are changed according to a preset algorithm.

16. The method for controlling a genetic algorithm accelerator of claim 15,
Wherein the resistance states of some memristor devices in the crossbar array block are set to a relatively high resistance state through a reset operation, and thereafter the resistance states of some other memristor devices are set to a relatively low resistance state through a set operation.

17. The method for controlling a genetic algorithm accelerator of claim 11,
wherein the genetic algorithm accelerator further comprises an evaluation circuit calculating fitness of the chromosome by performing a weighted sum operation based on preset weights corresponding to the respective memristor devices for each row comprised in the crossbar array block.

18. The method for controlling a genetic algorithm accelerator of claim 17,
wherein the evaluation circuit is based on a winner-take-all circuit.

19. The method for controlling a genetic algorithm accelerator of claim 17,
wherein the genetic algorithm accelerator further comprises a readout circuit externally reading out a chromosome evaluated to have the highest fitness by the evaluation circuit.

20. The method for controlling a genetic algorithm accelerator of claim 11,
wherein each of the plurality of memristor devices comprises a selector transistor to prevent a sneak path current by allowing a current to flow when the corresponding memristor device is activated.
